(19) United States
(12) Patent Application Publication
(10) Pub. No.: US 2012/0049281 A1
(43) Pub. Date: Mar. 1, 2012

(54) SEMICONDUCTOR DEVICE WITH EFFECTIVE WORK FUNCTION CONTROLLED METAL GATE

(75) Inventors: Yoshinori Tsuchiya, Clifton Park, NY (US); Ryosuke Iijima, Chappaqua, NY (US); Atsushi Yagishita, Voorheesville, NY (US)

(73) Assignee: TOSHIBA AMERICA ELECTRONIC COMPONENTS, INC., Irvine, CA (US)

(21) Appl. No.: 12/870,011

(22) Filed: Aug. 27, 2010

(51) Int. Cl. H01L 27/12; H01L 21/762

(52) U.S. Cl. 257/347; 438/479; 257/E21.561; 257/E27.112

(57) ABSTRACT

According to one embodiment, gate electrodes of a multi-gate field effect transistors and methods of making a gate electrode of a multi-gate field effect transistor are provided. The gate electrode can contain a semiconductor substrate; a dielectric layer over the semiconductor substrate; a fin over the dielectric layer; a gate insulating layer over the side surfaces of the fin; a gate electrode layer over the fin; and a polysilicon layer over the fin. The gate electrode does not contain a gate insulating layer over the upper surface of the dielectric layer except portions of the upper surface of the dielectric layer that contact with the side surfaces of the gate insulating layer formed over the side surface of the fin. In another embodiment, the gate electrode can contain an oxygen diffusion barrier layer or a first oxygen diffusion layer over the upper surface of the dielectric layer.

### FIELD

Embodiments described herein relate generally to semiconductor devices (e.g., multi-gate non-planar field effect transistors) with effective work function controlled metal gates and methods of making semiconductor devices with effective work function controlled metal gates.

### BACKGROUND

As transistor design is improved and evolved, the number of different types of transistors continues to increase. Multi-gate non-planar field effect transistors, including double-gate non-planar field effect transistors (e.g., finFETs) and tri-gate non-planar FETs, are developed to provide scaled devices with larger drive currents and reduced short channel effects over planar FETs.

Double-gate non-planar FETs are FETs in which a channel region is formed in a thin silicon fin sidewalls. Source and drain regions are formed in the opposing ends of the fin on either side of the channel region. Gates are formed over the thin silicon fin in areas corresponding to channel regions. FinFETs are a type of double-gate non-planar FETs in which the fin is so thin as to be fully depleted.

Tri-gate non-planar FETs have a similar structure to that of double-gate non-planar FETs; however, gates can be formed on three sides of the channel, including the top surface and the opposing sidewalls. The height to width ratio is generally larger than 1:1 so that the channel will remain fully depleted and the three-dimensional field effects of a tri-gate FET will give greater drive current and improved short-channel characteristics over a planar transistor.

### BRIEF DESCRIPTION OF THE DRAWINGS

FIGS. 1-18 are cross sectional views of exemplary gate electrodes in accordance with certain aspects of the subject innovation.

FIGS. 19 and 20 are cross sectional views of exemplary multi-gate field effect transistors in accordance with certain aspects of the subject innovation.

FIGS. 21-28 illustrate exemplary methodologies of forming a gate electrode in accordance with certain aspects of the subject innovation.

FIGS. 29 and 30 are flow diagrams of exemplary methodologies of forming a gate electrode in accordance with certain aspects of the subject innovation.

### DETAILED DESCRIPTION

One aspect of the innovation described herein can provide gate electrodes of a multi-gate metal field effect transistor. The devices, such as field effect transistors, can contain a semiconductor substrate; a dielectric layer over the semiconductor substrate; a fin over the dielectric layer; a gate insulating layer over the side surfaces of the fin; a gate electrode layer over the fin; and a polysilicon layer over the fin. The devices do not contain a gate insulating layer over the upper surface of the dielectric layer except portions of the upper surface of the dielectric layer that contact with the side surfaces of the gate insulating layer formed over the side surface of the fin.

Another aspect of the innovation can provide other gate electrodes of a multi-gate metal field effect transistor. The multi-gate metal field effect transistor can contain a semiconductor substrate; a dielectric layer over the semiconductor substrate; a fin over the dielectric layer; an oxygen diffusion barrier layer or a first oxygen diffusion layer over the upper surface of the dielectric layer; a gate insulating layer over the side surfaces of the fin; a gate electrode layer over the fin; and a polysilicon layer over the fin.

Yet another aspect of the innovation provides methods of making a gate electrode of a multi-gate metal field effect transistor. The method can involve forming a fin over a dielectric layer and a semiconductor substrate; forming a gate insulating layer over the side surfaces of the fin; foiining a gate electrode layer over the fin; and forming a polysilicon layer over the fin. The method, however, does not involve forming a gate insulating layer over the upper surface of the dielectric layer except portions of the upper surface of the dielectric layer that contact with the side surfaces of the gate insulating layer formed over the side surface of the fin.

Still yet another aspect of the innovation provides other methods of making a gate electrode of a multi-gate metal field effect transistor. The method can involve forming a fin over a dielectric layer and a semiconductor substrate; forming an oxygen diffusion barrier layer or a first oxygen diffusion layer over the upper surface of the dielectric layer; forming a gate insulating layer over the side surfaces of the fin; and forming a gate electrode layer over the fin; and forming a polysilicon layer over the fin.

In certain embodiments, effective work function of a gate electrode is controlled. The effective work function can be controlled by controlling an amount of oxygen diffusion from a transistor isolation region (e.g., a dielectric layer or buried silicon oxide (BOX) layer) to an interface of a gate insulating layer. The amount of oxygen diffusion can be controlled 1) by not forming a gate insulating layer over an upper surface of a dielectric layer, 2) by containing an oxygen diffusion barrier layer over an upper surface of a dielectric layer, 3) by containing an oxygen diffusion layer over an upper surface of a dielectric layer. The amount of oxygen diffusion can be decreased and the effective work function can be decreased by not forming a gate insulating layer over an upper surface of a dielectric layer and/or by containing an oxygen diffusion barrier layer over an upper surface of a dielectric layer. The amount of oxygen diffusion can be increased and the effective work function can be increased by containing an oxygen diffusion layer over an upper surface of a dielectric layer.

In certain embodiment, a multi-gate metal field effect transistor contains two or more gate electrodes that have different effective work functions from each other. For example, a multi-gate metal field effect transistor contains a first gate electrode and a second gate electrode and the effective work function of the first gate electrode is smaller than the effective work function of the second gate electrode.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram faun in order to facilitate describing the claimed subject matter.

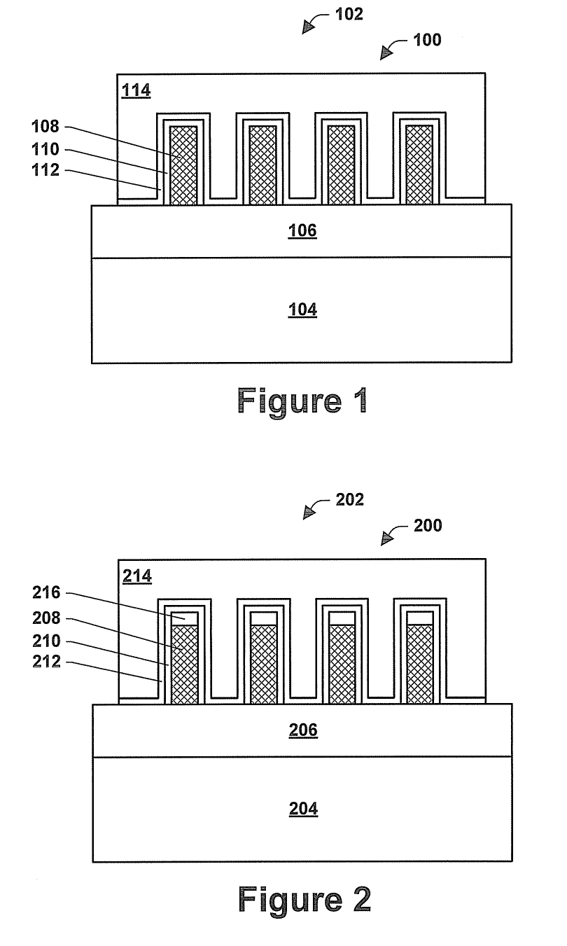

FIG. 1 illustrates a cross sectional view of an exemplary gate electrode 100 of a multi-gate field effect transistor 102. The gate electrode 100 can contain a semiconductor substrate (e.g., silicon substrate) 104; a dielectric layer (e.g., a buried silicon oxide layer or a BOX layer) 106 over the semiconductor substrate; a fin 108 over the dielectric layer; a gate insulating layer 110 over the side surfaces of the fin, a gate electrode layer 112 over the fin; and a polysilicon layer 114 over the fin. The gate electrode layer is provided over the fin via a gate insulating layer.

The transistor of the subject innovation can contain any suitable number of fins. In one embodiment, the transistor contains one fin. In another embodiment, the transistor contains two or more fins. Although four fins are shown in FIG. 1 and in the subsequent Figures for the purpose of brevity, the subject transistor can contain any suitable number of fins depending on a type of the transistor.

The channel of the transistor 102 can be doped to produce either an N-type semiconductor or a P-type semiconductor. In one embodiment, the transistor 102 is an N-type field effect transistor. In another embodiment, the transistor 102 is a P-type field effect transistor. In the subsequent embodiment, transistors can be an N-type field effect transistor or a P-type field effect transistor.

The fin typically contains silicon. The fin has a substantially rectangular parallelepiped shape. The dimensions of the substantially rectangular parallelepiped shape have a suitable length depending on the desired implementations of the transistor being fabricated. In one embodiment, the height of the fin is about 20 nm or more and about 200 nm or less. In another embodiment, the height of the fin is about 30 nm or more and about 180 nm or less. In yet another embodiment, the height of the fin is about 40 nm or more and about 160 nm or less.

In one embodiment, the short sides of the upper and lower surfaces of the fin are about 5 nm or more and about 100 nm or less. In another embodiment, the short sides of the upper and lower surfaces of the fin are about 7 nm or more and about 70 nm or less. In yet another embodiment, the short sides of the upper and lower surfaces of the fin are about 10 nm or more and about 50 nm or less.

In one embodiment, the long sides of the upper and lower surfaces of the fin are about 300 nm or more and about 1,500 nm or less. In another embodiment, the long sides of the upper and lower surfaces of the fin are about 400 nm or more and about 1,300 nm or less. In yet another embodiment, the long sides of the upper and lower surfaces of the fin are about 500 urn or more and about 1,000 nm or less.

The gate insulating layer is formed over the side surface of the fin. The gate insulating layer can be formed over the upper surface of the fin. The gate insulating layer, however, is not formed over the upper surface of the dielectric layer except portions of the upper surface of the dielectric layer that contact with the side surfaces (e.g., edges) of the gate insulating layer formed over the side surface of the fin. The gate insulating layer is not formed over the upper surface of the dielectric layer except adjacent portions of the upper surface of the dielectric layer to the side surfaces of the fin. The length of the adjacent portion over which the gate insulating layer is formed is about equal to the thickness of the gate insulating layer. Only the side surface or the edge of the gate insulating layer is in contact with the upper surface of the dielectric layer.

In one embodiment, about 80% or more and about 99.9% of less of the upper surface area of dielectric layer of the gate electrode is not covered with the gate insulating layer. In another embodiment, about 90% or more and about 99.9% of less of the upper surface area of dielectric layer of the gate electrode is not covered with the gate insulating layer. In yet another embodiment, about 95% or more and about 99.9% of less of the upper surface area of dielectric layer of the gate electrode is not covered with the gate insulating layer.

A portion of the gate electrode can be directly in contact with the upper surface of the dielectric layer. In one embodiment, about 80% or more and about 99.9% of less of the upper surface area of dielectric layer of the gate electrode is directly in contact with the gate electrode layer. In another embodiment, about 90% or more and about 99.9% of less of the upper surface area of dielectric layer of the gate electrode is directly in contact with the gate electrode layer. In yet another embodiment, about 95% or more and about 99.9% of less of the upper surface area of dielectric layer of the gate electrode is directly in contact with the gate electrode layer.

The gate insulating layer can contain any suitable insulating material. In one embodiment, heat of formation (AH_{f}) of the gate insulating layer is negatively greater than heat of formation of the dielectric layer. In another embodiment, the gate insulating layer has heat of formation of about −900 kJ/mol or more and about −2300 kJ/mol or less, and the dielectric layer has heat of formation of about −100 kJ/mol or more and about −1700 kJ/mol or less. In yet another embodiment, the gate insulating layer has heat of formation of about −1100 kJ/mol or more and about −1800 kJ/mol or less, and the dielectric layer has heat of formation of about −300 kJ/mol or more and about −1500 kJ/mol or less. In still yet another embodiment, the gate insulating layer has heat of formation of about −1500 kJ/mol or more and about −1800 kJ/mol or less, and the dielectric layer has heat of formation of about −500 kJ/mol or more and about −1200 kJ/mol or less.

In one embodiment, a dielectric constant of (k) of the gate insulating layer is greater than a dielectric constant of the dielectric layer. The gate insulating layer typically has a dielectric constant of greater than about 3.9. In another embodiment, the gate insulating layer has a dielectric constant of about 4.5 or more and about 200 or less, and the dielectric layer has a dielectric constant of about 2 or more and about 50 or less. In yet another embodiment, the gate insulating layer has a dielectric constant of about 4.5 or more and about 50 or less, and the dielectric layer has a dielectric constant of about 2 or more and about 30 or less. In still yet another embodiment, the gate insulating layer has a dielectric constant of about 4.5 or more and about 25 or less, and the dielectric layer has a dielectric constant of about 2 or more and about 10 or less.

The gate insulating layer can contain a suitable high-k material. Examples of high-k materials include a metal oxide, such as hafnium oxide (HfO₂), hafnium silicate (HfSiO), aluminum oxide (Al₂O₃), tantalum oxide (Ta₂O₅), titanium oxide (TiO₂), zirconium oxide (ZrO₂), hafnium oxide (HfO₂), yttrium oxide (Y₂O₃), silicon zirconium oxide (SiZrO₄), lanthanum oxide (La₂O₃), other corresponding silicates, or the like.

The gate insulating layer has a suitable thickness depending on the desired implementations of the transistor being fabricated. In one embodiment, the thickness of the gate insulating layer is about 0.1 nm or more and about 20 nm or less. In another embodiment, the thickness of the gate insulating layer is about 0.1 nm or more and about 10 nm or less. In yet another embodiment, the thickness of the gate insulating layer is about 0.1 nm or more and about 5 nm or less.

The gate electrode layer is formed over gate insulating layer and over the side surface of the fin. The gate electrode layer can be formed over the upper surface of the fin and the upper surface of the dielectric layer. The gate electrode layer can be directly in contact with the upper surface of the dielectric layer.

The gate electrode layer can contain a suitable electrically conductive material including metals and metal compounds. In one embodiment, the gate electrode layer contains metals, metal compounds, and combinations of thereof that have a melting point of about 500 degrees Celsius or more. Example of metals and metal compounds include tungsten (W), aluminum (Al), copper (Cu), gold (Au), titanium nitride (TiN), titanium carbide (TiC), titanium carbonitride (TiCN), tantalum nitride (TaN), titanium silicon nitride (TiSiN), and combinations thereof.

The gate electrode layer has a suitable thickness depending on the desired implementations of the transistor being fabricated. In one embodiment, the thickness of the gate electrode layer is about 0.1 nm or more and about 20 nm or less. In another embodiment, the thickness of the gate electrode layer is about 0.1 nm or more and about 10 nm or less. In yet another embodiment, the thickness of the gate electrode layer is about 0.1 nm or more and about 5 nm or less.

Although not illustrated in FIG. 1, the gate electrode can contain one or more other features including cap layers and ions to control (e.g., decrease or increase) an effective work function. In one embodiment, the gate electrode contains one or more cap layers over at least one of the gate insulating layer, the gate electrode layer, and combinations of thereof. The cap layer can contain any suitable material so that the cap layer can provide the gate electrode with a suitable effective work function. Examples of the materials of the cap layer include lanthanum oxide (La₂O₃), aluminum oxide (Al₂O₃), or the like.

In another embodiment, the gate electrode contains ions in one or more components of the gate electrode to control (e.g., decrease or increase) an effective work function. The ions can be contained in at least the gate insulating layer, the interface between the fin and the gate electrode layer, the interface between the gate electrode layer and the gate insulating layer, or combinations thereof. Examples of ions include aluminum (Al), nitrogen (N), arsenic (As), fluorine (F), indium (In), or the like. The ions can be introduced into the one or more components by ion implantation. The ions can be implanted at a dose of about 1×10¹⁵ atoms/cm² or more and about 5×10¹⁶ atoms/cm² or less and at an energy level of about 2 KeV or more and about 40 KeV or less, for example.

The gate electrode can have an effective work function of about 4.6 eV or less. In one embodiment, the gate electrode has an effective work function of about 4.5 eV or less. In another embodiment, the gate electrode has an effective work function of about 4.2 eV or less. In yet another embodiment, the gate electrode has an effective work function of about 4.0 eV or less.

FIG. 2 illustrates a cross sectional view of another exemplary gate electrode 200 of a multi-gate field effect transistor 202. The gate electrode 200 can contain a semiconductor substrate (e.g., silicon substrate) 204; a dielectric layer (e.g., a buried silicon oxide layer or a BOX layer) 206 over the semiconductor substrate; a fin 208 over the dielectric layer; a gate insulating layer 210 over the side surfaces of the fin, a gate electrode layer 212 over the fin; and a polysilicon layer 214 over the fin.

The gate electrode 200 contains the semiconductor substrate 204, the dielectric layer 206, the fin 208, the gate insulating layer 210, the gate electrode layer 212, and the polysilicon layer 214 in the same manner as the gate electrode 100 as described in connection with FIG. 1 except that the gate electrode 200 further contains a hard mask layer 216 over the upper surface of the fin. Since the gate electrode 200 contains the hard mask layer over the upper surface of the fin, the gate insulating layer and the gate electrode layer can be formed over the upper surface and side surfaces of the hard mask. In the same manner as the gate electrode 100 as described in connection with FIG. 1, the gate insulating layer 210 is not formed over the upper surface of the dielectric layer except portions of the upper surface of the dielectric layer that contact with the side surfaces of the gate insulating layer formed over the side surface of the fin.

The hard mask layer can contain any suitable material that has smaller oxygen diffusion coefficient so that the gate electrode can have a low effective work function. The hard mask layer can have smaller oxygen diffusion coefficient than the dielectric layer. In one embodiment, the hard mask has an oxygen diffusion coefficient that is smaller than that of the dielectric layer by about 1×10⁻²⁵ cm²·s⁴ or more and about 1×10⁴³ cm²·s⁴ or less. In another embodiment, the hard mask has an oxygen diffusion coefficient that is smaller than that of the dielectric layer by about 1×10⁻²³ cm²·s⁴ or more and about 1×10⁻¹⁴ cm²·s⁻¹ or less. In yet another embodiment, the hard mask has an oxygen diffusion coefficient that is smaller than that of the dielectric layer by about 1×10⁻²⁰ cm²·s⁻¹ or more and about 1×10⁻¹⁵ cm²·s⁻¹ or less.

The hard mask can contain a smaller interstitial oxygen concentration than the dielectric layer. In one embodiment, the hard mask has an interstitial oxygen concentration that is smaller than that of the dielectric layer by about 1×10¹⁶ atoms·cm⁻³ or more and about 5×10²¹ atoms·cm⁻³ or less. In another embodiment, the hard mask has an interstitial oxygen concentration that is smaller than that of the dielectric layer by about 1×10¹⁷ atoms·cm⁻³ or more and about 2×10²¹ atoms·cm⁻³ or less. In yet another embodiment, the hard mask has an interstitial oxygen concentration that is smaller than that of the dielectric layer by about 1×10¹⁸ atoms·cm⁻³ or more and about 5×10²° atoms·cm⁻³ or less.

The hard mask can contain a larger interstitial nitrogen concentration than the dielectric layer. In one embodiment, the hard mask has an interstitial nitrogen concentration that is larger than that of the dielectric layer by about 1×10²⁰ atoms·cm⁻³ or more and about 5×10²³ atoms·cm⁻³ or less. In another embodiment, the hard mask has an interstitial nitrogen concentration that is larger than that of the dielectric layer by about 1×10²¹ atoms·cm⁻³ or more and about 5×10²³ atoms·cm⁻³ or less. In yet another embodiment, the hard mask has an interstitial nitrogen concentration that is larger than that of the dielectric layer by about 1×10²² atoms·cm⁻³ or more and about 5×10²³ atoms·cm⁻³ or less. In still yet another embodiment, the hard mask has an interstitial nitrogen concentration of about 1×10²⁰ atoms·cm³ or more. The hard mask can contain nitrides. Examples of nitrides include silicon oxynitride (SiON), silicon nitride (SiN), or the like.

The hard mask layer has a suitable thickness depending on the desired implementations of the transistor being fabricated. In one embodiment, the thickness of the hard mask layer is about 1 nm or more and about 50 nm or less. In another embodiment, the thickness of the hard mask layer is about 3 nm or more and about 40 nm or less. In yet another embodiment, the thickness of the hard mask layer is about 5 nm or more and about 30 nm or less.

The gate electrode does not necessarily contain the gate insulating layer and/or the gate electrode layer over the upper surface of the hard mask. Although now shown in FIG. 2, in one embodiment, the gate electrode does not contain the gate insulating layer over the upper surface of the hard mask. In another embodiment, the gate electrode does not contain the gate electrode layer over the upper surface of the hard mask. In yet another embodiment, the gate electrode does not contain the gate insulating layer and the gate electrode layer over the upper surface of the hard mask.

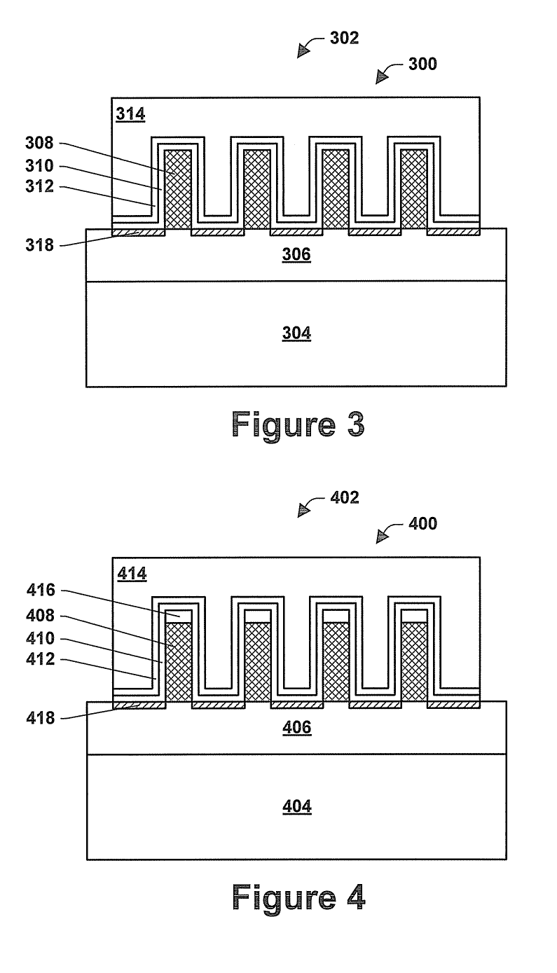

FIG. 3 illustrates a cross sectional view of another exemplary gate electrode 300 of a multi-gate field effect transistor 302. The gate electrode 300 can contain a semiconductor substrate (e.g., silicon substrate) 304; a dielectric layer (e.g., a buried silicon oxide layer or a BOX layer) 306 over the semiconductor substrate; a fin 308 over the dielectric layer; an oxygen diffusion barrier layer 318 over the upper surface of the dielectric layer; a gate insulating layer 310 over the side surfaces of the fin; a gate electrode layer 312 over the fin; and a polysilicon layer 314 over the fin. The channel of the transistor 302 can be doped to produce either an N-type semiconductor or a P-type semiconductor. In one embodiment, the transistor 302 is a P-type field effect transistor.

The gate electrode 300 contains the semiconductor substrate 304, the dielectric layer 306, the fin 308, the gate insulating layer 310, the gate electrode layer 312, and the polysilicon layer 314 in the same manner as the gate electrode 100 as described in connection with FIG. 1 except that the gate electrode 300 further contains the oxygen diffusion barrier layer 318 over the upper surface of the dielectric layer and except that the gate electrode 300 contains the gate insulating layer 310 over the upper surface of the dielectric layer. The oxygen diffusion barrier layer is formed over the upper surface of the dielectric layer and the gate insulating layer is formed over the oxygen diffusion barrier layer.

The oxygen diffusion barrier layer can contain any suitable material that can prevent or mitigate oxygen diffusion from the dielectric layer 306 to the polysilicon layer 314. In other words, the oxygen diffusion barrier layer can have smaller oxygen diffusion coefficient than the dielectric layer. In one embodiment, the oxygen diffusion barrier layer has an oxygen diffusion coefficient that is smaller than that of the dielectric layer by about 1×10⁻²⁵ cm⁻²·s⁻¹ or more and about 1×10⁻¹³ cm²·s⁻¹ or less. In another embodiment, the oxygen diffusion barrier layer has an oxygen diffusion coefficient that is smaller than that of the dielectric layer by about 1×10⁻²³ cm²·s⁻¹ or more and about 1×10⁻¹⁴ cm²·s⁻¹ or less. In yet another embodiment, the oxygen diffusion barrier layer has an oxygen diffusion coefficient that is smaller than that of the dielectric layer by about 1×10⁻²⁰ cm²·s⁻¹ m²·s⁻¹ or more and about 1×10⁻¹⁵ cm²·s⁻¹ or less.

The oxygen diffusion barrier layer can contain a smaller interstitial oxygen concentration than the dielectric layer. In one embodiment, the oxygen diffusion barrier layer has an interstitial oxygen concentration that is smaller than that of the dielectric layer by about 1×10¹⁶ atoms-cm⁻³ or more and about 5×10²¹ atoms·cm⁻³ or less. In another embodiment, the oxygen diffusion barrier layer has an interstitial oxygen concentration that is smaller than that of the dielectric layer by about 1×10¹⁷ atoms·cm⁻³ or more and about 1×10²¹ atoms·cm⁻³ or less. In yet another embodiment, the oxygen diffusion barrier layer has an interstitial oxygen concentration that is smaller than that of the dielectric layer by about 1×10¹⁸ atoms·cm⁻³ or more and about 1×10²⁰ atoms·cm⁻³ or less.

The oxygen diffusion barrier layer can contain a larger interstitial nitrogen concentration than the dielectric layer. In one embodiment, the oxygen diffusion barrier layer has an interstitial nitrogen concentration that is larger than that of the dielectric layer by about 1×10¹⁶ atoms·cm³ or more and about 5×10²¹ atoms·cm⁻³ or less. In another embodiment, the oxygen diffusion barrier layer has an interstitial nitrogen concentration that is larger than that of the dielectric layer by about 1×10¹⁷ atoms·cm⁻³ or more and about 1×10²¹ atoms·cm⁻³ or less. In yet another embodiment, the oxygen diffusion barrier layer has an interstitial nitrogen concentration that is larger than that of the dielectric layer by about 1×10¹⁸ atoms·cm⁻³ or more and about 1×10²⁰ atoms·cm⁻³ or less. In still yet another embodiment, the oxygen diffusion barrier layer has an interstitial nitrogen concentration of about 1×10²⁰ atoms·cm⁻³ or more.

The oxygen diffusion barrier layer has a suitable thickness depending on the desired implementations of the transistor being fabricated. In one embodiment, the thickness of the oxygen diffusion barrier layer is about 1 nm or more and about 50 nm or less. In another embodiment, the thickness of the oxygen diffusion barrier layer is about 3 nm or more and about 40 nm or less. In yet another embodiment, the thickness of the oxygen diffusion barrier layer is about 5 nm or more and about 30 nm or less.

FIG. 4 illustrates a cross sectional view of another exemplary gate electrode 400 of a multi-gate field effect transistor 402. The gate electrode 400 can contain a semiconductor substrate (e.g., silicon substrate) 404; a dielectric layer (e.g., a buried silicon oxide layer or a BOX layer) 406 over the semiconductor substrate; a fin 408 over the dielectric layer; a hard mask layer 416 over the upper surface of the fin; an oxygen diffusion barrier layer 418 over the upper surface of the dielectric layer; a gate insulating layer 410 over the side surfaces of the fin, a gate electrode layer 412 over the fin; and a polysilicon layer 414 over the fin.

The gate electrode 400 contains the semiconductor substrate 404, the dielectric layer 406, the fin 408, the gate insulating layer 410, the gate electrode layer 412, and the polysilicon layer 414 in the same manner as the gate electrode 300 as described in connection with FIG. 3 except that the gate electrode 400 further contains the hard mask layer 416 over the upper surface of the fin. Since the gate electrode 400 contains the hard mask layer over the upper surface of the fin, the gate insulating layer and the gate electrode layer can be formed over the upper surface and side surfaces of the hard mask.

The gate electrode does not necessarily contain the gate insulating layer and/or the gate electrode layer over the upper surface of the hard mask. Although now shown in FIG. 4, in one embodiment, the gate electrode does not contain the gate insulating layer over the upper surface of the hard mask. In another embodiment, the gate electrode does not contain the gate electrode layer over the upper surface of the hard mask. In yet another embodiment, the gate electrode does not contain the gate insulating layer and the gate electrode layer over the upper surface of the hard mask.

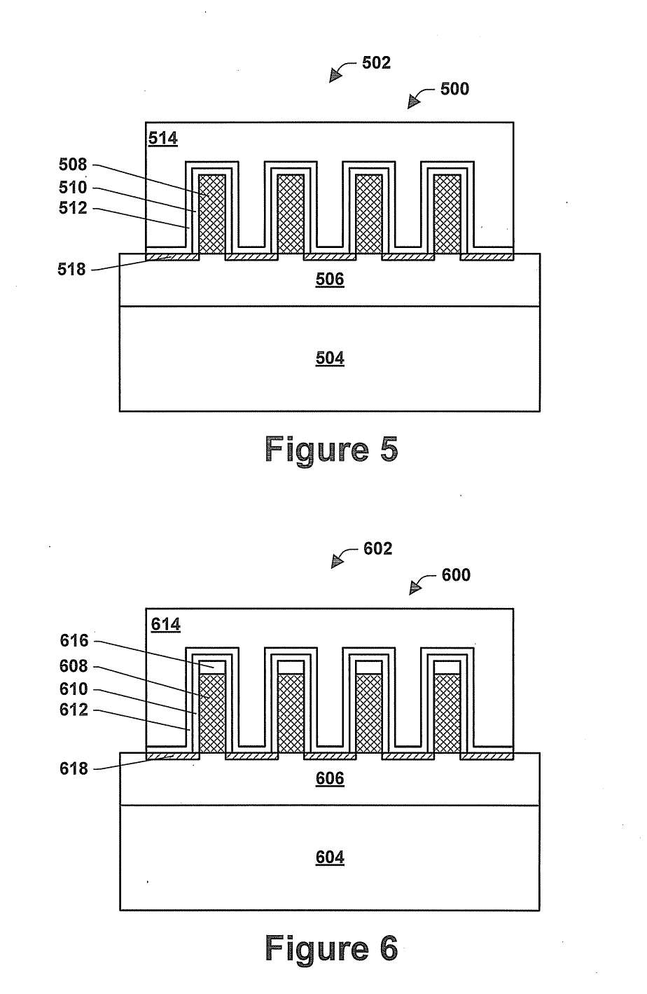

FIG. 5 illustrates a cross sectional view of another exemplary gate electrode 500 of a multi-gate field effect transistor 502. The gate electrode 500 can contain a semiconductor substrate (e.g., silicon substrate) 504; a dielectric layer (e.g., a buried silicon oxide layer or a BOX layer) 506 over the semiconductor substrate; a fin 508 over the dielectric layer; an oxygen diffusion barrier layer 518 over the upper surface of the dielectric layer; a gate insulating layer 510 over the side surfaces of the fin; a gate electrode layer 512 over the fin; and a polysilicon layer 514 over the fin.

The gate electrode 500 contains the semiconductor substrate 504, the dielectric layer 506, the fin 508, the gate insulating layer 510, the gate electrode layer 512, and the polysilicon layer 514 in the same manner as the gate electrode 100 as described in connection with FIG. 1 except that the gate electrode 500 further contains the oxygen diffusion barrier layer 518 over the upper surface of the dielectric layer. The oxygen diffusion barrier layer is formed over the upper surface of the dielectric layer. The gate insulating layer is not formed over the upper surface of the dielectric layer (e.g., BOX layer) except portions of the upper surface of the dielectric layer that contact with the side surfaces of the gate insulating layer formed over the side surface of the fin in the same manner as the transistor 100 as described in connection with FIG. 1.

FIG. 6 illustrates a cross sectional view of another exemplary gate electrode 600 of a multi-gate field effect transistor 602. The gate electrode 600 can contain a semiconductor substrate (e.g., silicon substrate) 604; a dielectric layer (e.g., a buried silicon oxide layer or a BOX layer) 606 over the semiconductor substrate; a fin 608 over the dielectric layer; an oxygen diffusion barrier layer 618 over the upper surface of the dielectric layer; a hard mask layer 616 over the upper surface of the fin; a gate insulating layer 610 over the side surfaces of the fin, a gate electrode layer 612 over the fin; and a polysilicon layer 614 over the fin.

The gate electrode 600 contains the semiconductor substrate 604, the dielectric layer 606, the fin 608, the oxygen diffusion barrier layer 618; the gate insulating layer 610, the gate electrode layer 612, and the polysilicon layer 614 in the same manner as the gate electrode 500 as described in connection with FIG. 5 except that the gate electrode 600 further contains a hard mask layer 616 over the upper surface of the fin. Since the gate electrode 600 contains the hard mask layer over the upper surface of the fin, the gate insulating layer and the gate electrode layer can be formed over the upper surface and side surfaces of the hard mask.

The gate electrode does not necessarily contain the gate insulating layer and/or the gate electrode layer over the upper surface of the hard mask. Although now shown in FIG. 6, in one embodiment, the gate electrode does not contain the gate insulating layer over the upper surface of the hard mask. In another embodiment, the gate electrode does not contain the gate electrode layer over the upper surface of the hard mask. In yet another embodiment, the gate electrode does not contain the gate insulating layer and the gate electrode layer over the upper surface of the hard mask.

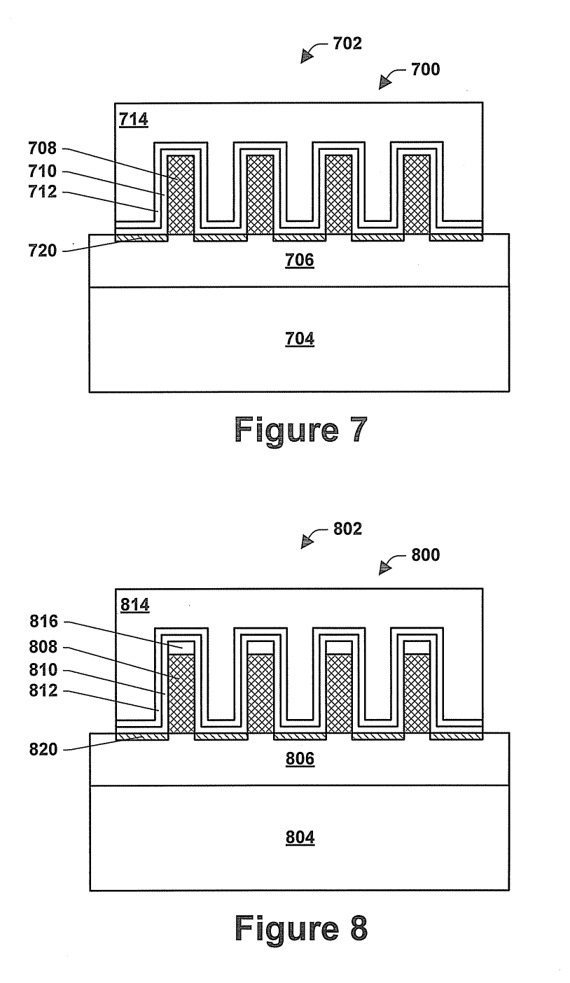

FIG. 7 illustrates a cross sectional view of another exemplary gate electrode 700 of a multi-gate field effect transistor 702. The gate electrode 700 can contain a semiconductor substrate (e.g., silicon substrate) 704; a dielectric layer (e.g., a buried silicon oxide layer or a BOX layer) 706 over the semiconductor substrate; a fin 708 over the dielectric layer; a first oxygen diffusion layer 720 over the upper surface of the dielectric layer; a gate insulating layer 710 over the side surfaces of the fin; a gate electrode layer 712 over the fin; and a polysilicon layer 714 over the fin. The channel of the transistor 702 can be doped to produce either an N-type semiconductor or a P-type semiconductor. In one embodiment, the transistor 702 is an N-type field effect transistor.

The gate electrode 700 contains the semiconductor substrate 704, the dielectric layer 706, the fin 708, the hard mask layer 716, the gate insulating layer 710, the gate electrode layer 712, and the polysilicon layer 714 in the same manner as the gate electrode 100 as described in connection with FIG. 1 except that the gate electrode 700 further contains the first oxygen diffusion layer 720 over the upper surface of the dielectric layer and except that the gate electrode 700 contains the gate insulating layer 710 over the upper surface of the dielectric layer. The first oxygen diffusion layer is formed over the upper surface of the dielectric layer and the gate insulating layer 710 is formed over the first oxygen diffusion layer.

The first oxygen diffusion layer can contain any suitable material that can enhance oxygen diffusion from the dielectric layer 706 to the polysilicon layer 714. In other words, the first oxygen diffusion layer can have larger oxygen diffusion coefficient than the dielectric layer. In one embodiment, the first oxygen diffusion layer has an oxygen diffusion coefficient that is larger than that of the dielectric layer by about 1×10⁻²⁰ cm² s⁻¹ or more and about 1×10⁻¹⁰ cm² s⁻¹ or less. In another embodiment, the first oxygen diffusion layer has an oxygen diffusion coefficient that is larger than that of the dielectric layer by about 1×10⁻¹⁸ cm² s⁻¹ or more and about 1×10⁻¹³ cm² s⁻¹ or less. In yet another embodiment, the first oxygen diffusion layer has an oxygen diffusion coefficient that is larger than that of the dielectric layer by about 1×10⁻¹⁶ m² s⁻¹ or more and about 1×10⁻¹⁵ m² s⁻¹ or less.

The first oxygen diffusion layer can contain a larger interstitial oxygen concentration than the dielectric layer. In one embodiment, the first oxygen diffusion layer has an interstitial oxygen concentration that is larger than that of the dielectric layer by about 5×10¹⁹ atoms·cm⁻³ or more and about 5×10²³ atoms·cm⁻³ or less. In another embodiment, the first oxygen diffusion layer has an interstitial oxygen concentration that is larger than that of the dielectric layer by about 5×10²⁰ atoms·cm³ or more and about 5×10²³ atoms·cm⁻³ or less. In yet another embodiment, the first oxygen diffusion layer has an interstitial oxygen concentration that is larger than that of the dielectric layer by about 5×10²¹ atoms·cm⁻³ or more and about 5×10²³ atoms·cm⁻³ or less.

The first oxygen diffusion layer can contain any suitable oxides. Specific examples of materials of first oxygen diffusion layer include disordered silicon oxide (e.g., SiO₂), oxygen-rich silicon oxide, tetraethylorthosilicate (TEOS), high density plasma (HDP) oxide, or the like.

The first oxygen diffusion layer has a suitable thickness depending on the desired implementations of the transistor being fabricated. In one embodiment, the thickness of the first oxygen diffusion layer is about 5 nm or more and about 50 nm or less. In another embodiment, the thickness of the first oxygen diffusion layer is about 7 nm or more and about 40 nm or less. In yet another embodiment, the thickness of the first oxygen diffusion layer is about 10 nm or more and about 30 nm or less.

The gate electrode 700 can have an effective work function of about 4.6 eV or more. In one embodiment, the gate electrode has an effective work function of about 4.7 eV or more. In another embodiment, the gate electrode has an effective work function of about 5.0 eV or more. In yet another embodiment, the gate electrode has an effective work function of about 5.2 eV or more.

FIG. 8 illustrates a cross sectional view of another exemplary gate electrode 800 of a multi-gate field effect transistor 802. The gate electrode 800 can contain a semiconductor substrate (e.g., silicon substrate) 804; a dielectric layer (e.g., a buried silicon oxide layer or a BOX layer) 806 over the semiconductor substrate; a fin 808 over the dielectric layer; a hard mask layer 816 over the upper surface of the fin; a first oxygen diffusion layer 820 over the upper surface of the dielectric layer; a gate insulating layer 810 over the side surfaces of the fin, a gate electrode layer 812 over the fin; and a polysilicon layer 814 over the fin.

The gate electrode 800 contains the semiconductor substrate 804, the dielectric layer 806, the fin 808, the gate insulating layer 810, the gate electrode layer 812, and the polysilicon layer 814, the first oxygen diffusion layer 820 in the same manner as the gate electrode 700 as described in connection with FIG. 7 except that the gate electrode 800 further contains the hard mask layer 816 over the upper surface of the fin. Since the gate electrode 800 contains the hard mask layer over the upper surface of the fin, the gate insulating layer and the gate electrode layer can be formed over the upper surface and side surfaces of the hard mask.

The gate electrode does not necessarily contain the gate insulating layer and/or the gate electrode layer over the upper surface of the hard mask. Although now shown in FIG. 8, in one embodiment, the gate electrode does not contain the gate insulating layer over the upper surface of the hard mask. In another embodiment, the gate electrode does not contain the gate electrode layer over the upper surface of the hard mask. In yet another embodiment, the gate electrode does not contain the gate insulating layer and the gate electrode layer over the upper surface of the hard mask.

The gate insulating layer and/or the gate electrode layer are not necessarily formed over the upper surface of the hard mask. Although now shown in FIG. 8, in one embodiment, the gate insulating layer is not formed over the upper surface of the hard mask. In another embodiment, the gate electrode layer is not formed over the upper surface of the hard mask. In yet another embodiment, the gate insulating layer and the gate electrode layer are not formed over the upper surface of the hard mask.

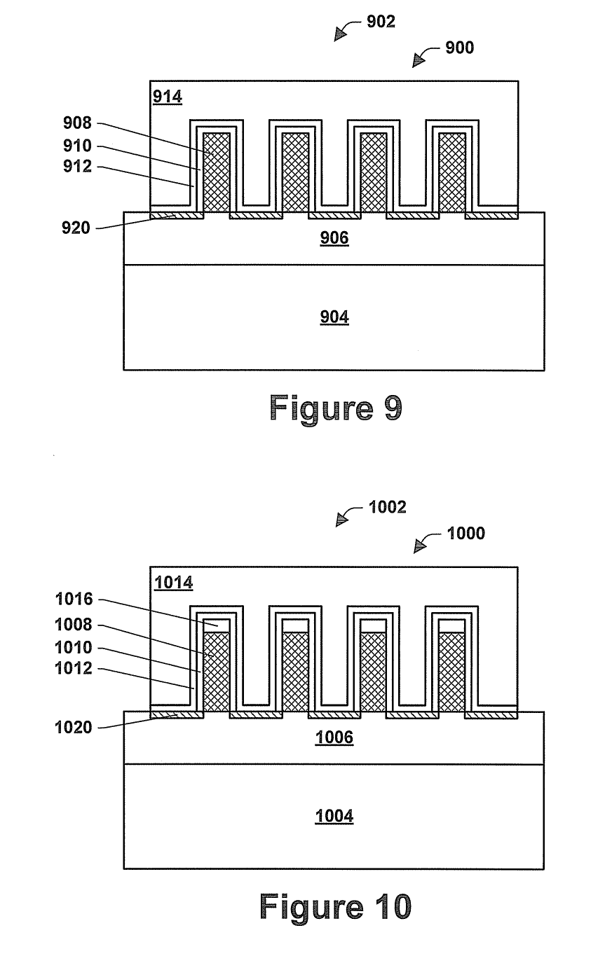

FIG. 9 illustrates a cross sectional view of another exemplary gate electrode 900 of a multi-gate field effect transistor 902. The gate electrode 900 can contain a semiconductor substrate (e.g., silicon substrate) 904; a dielectric layer (e.g., a buried silicon oxide layer or a BOX layer) 906 over the semiconductor substrate; a fin 908 over the dielectric layer; a first oxygen diffusion layer 920 over the upper surface of the dielectric layer; a gate insulating layer 910 over the side surfaces of the fin; a gate electrode layer 912 over the fin; and a polysilicon layer 914 over the fin.

The gate electrode 900 contains the semiconductor substrate 904, the dielectric layer 906, the fin 908, the gate insulating layer 910, the gate electrode layer 912, and the polysilicon layer 914 in the same manner as the gate electrode 100 as described in connection with FIG. 1 except that the gate electrode 900 further contains the first oxygen diffusion layer 920 over the upper surface of the dielectric layer. The first oxygen diffusion layer is formed over the upper surface of the dielectric layer. The gate insulating layer is not formed over the upper surface of the dielectric layer (e.g., BOX layer) except portions of the upper surface of the dielectric layer that contact with the side surfaces of the gate insulating layer formed over the side surface of the fin in the same manner as the transistor 100 as described in connection with FIG. 1.

FIG. 10 illustrates a cross sectional view of another exemplary gate electrode 1000 of a multi-gate field effect transistor 1002. The gate electrode 1000 can contain a semiconductor substrate (e.g., silicon substrate) 1004; a dielectric layer (e.g., a buried silicon oxide layer or a BOX layer) 1006 over the semiconductor substrate; a fin 1008 over the dielectric layer; a first oxygen diffusion layer 1020 over the upper surface of the dielectric layer; a hard mask layer 1016 over the upper surface of the fin; a gate insulating layer 1010 over the side surfaces of the fin, a gate electrode layer 1012 over the fin; and a polysilicon layer 1014 over the fin.

The gate electrode 1000 contains the semiconductor substrate 1004, the dielectric layer 1006, the fin 1008, the first oxygen diffusion layer 1020; the gate insulating layer 1010, the gate electrode layer 1012, and the polysilicon layer 1014 in the same manner as the gate electrode 900 as described in connection with FIG. 9 except that the gate electrode 1000 further contains the hard mask layer 1016 over the upper surface of the fin. Since the gate electrode 1000 contains the hard mask layer over the upper surface of the fin, the gate insulating layer and the gate electrode layer can be formed over the upper surface and side surfaces of the hard mask.

The gate electrode does not necessarily contain the gate insulating layer and/or the gate electrode layer over the upper surface of the hard mask. Although now shown in FIG. 10, in one embodiment, the gate electrode does not contain the gate insulating layer over the upper surface of the hard mask. In another embodiment, the gate electrode does not contain the gate electrode layer over the upper surface of the hard mask. In yet another embodiment, the gate electrode does not contain the gate insulating layer and the gate electrode layer over the upper surface of the hard mask.

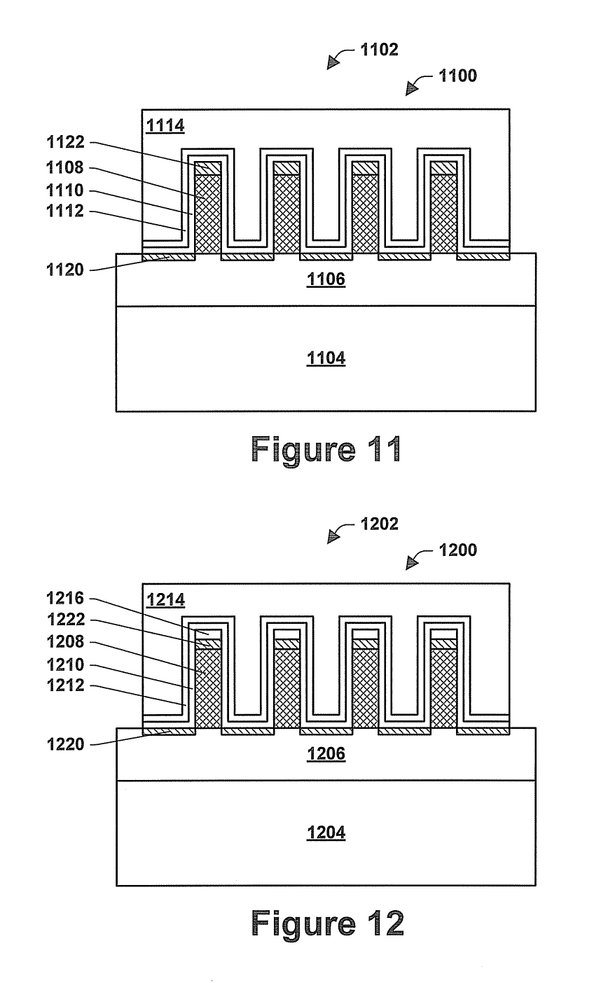

FIG. 11 illustrates a cross sectional view of another exemplary gate electrode 1100 of a multi-gate field effect transistor 1102. The gate electrode 1100 can contain a semiconductor substrate (e.g., silicon substrate) 1104; a dielectric layer (e.g., a buried silicon oxide layer or a BOX layer) 1106 over the semiconductor substrate; a fin 1108 over the dielectric layer; a first oxygen diffusion layer 1120 over the upper surface of the dielectric layer; a second oxygen diffusion layer 1122 over the upper surface of the fin; a gate insulating layer 1110 over the side surfaces of the fin, a gate electrode layer 1112 over the fin; and a polysilicon layer 1114 over the fin. The second oxygen diffusion layer can contain the material of the first oxygen diffusion layer 720 as described in connection with FIG. 7.

The gate electrode 1100 contains the semiconductor substrate 1104, the dielectric layer 1106, the fin 1108, the first oxygen diffusion layer 1120, the second oxygen diffusion layer 1122, the gate insulating layer 1110, the gate electrode layer 1112, and the polysilicon layer 1114 in the same manner as the gate electrode 700 as described in connection with FIG. 7 except that the gate electrode 1100 further contains the second oxygen diffusion layer 1116 over the upper surface of the fin. Since the gate electrode 1100 contains the second oxygen diffusion layer over the upper surface of the fin, the gate insulating layer and the gate electrode layer can be formed over the upper surface and side surfaces of the second oxygen diffusion.

The gate electrode does not necessarily contain the gate insulating layer and/or the gate electrode layer over the upper surface of the second oxygen diffusion. Although now shown in FIG. 11, in one embodiment, the gate electrode does not contain the gate insulating layer over the upper surface of the second oxygen diffusion. In another embodiment, the gate electrode does not contain the gate electrode layer over the upper surface of the second oxygen diffusion. In yet another embodiment, the gate electrode does not contain the gate insulating layer and the gate electrode layer over the upper surface of the second oxygen diffusion.

FIG. 12 illustrates a cross sectional view of another exemplary gate electrode 1200 of a multi-gate field effect transistor 1202. The gate electrode 1200 can contain a semiconductor substrate (e.g., silicon substrate) 1204; a dielectric layer (e.g., a buried silicon oxide layer or a BOX layer) 1206 over the semiconductor substrate; a fin 1208 over the dielectric layer; a first oxygen diffusion layer 1220 over the upper surface of the dielectric layer; a second oxygen diffusion layer 1122 over the upper surface of the fin; a hard mask layer 1216 over the upper surface of the second oxygen diffusion layer; a gate insulating layer 1210 over the side surfaces of the fin, a gate electrode layer 1212 over the fin; and a polysilicon layer 1214 over the fin.

The gate electrode 1200 contains the semiconductor substrate 1204, the dielectric layer 1206, the fin 1208, the first oxygen diffusion layer 1220, the second oxygen diffusion layer 1222, the hard mask 1216, the gate insulating layer 1210, the gate electrode layer 1212, and the polysilicon layer 1214 in the same mariner as the gate electrode 1100 as described in connection with FIG. 11 except that the gate electrode 1200 further contains the hard mask layer 1216 over the upper surface of the second oxygen diffusion layer. Since the gate electrode 1200 contains the hard mask layer over the upper surface of the second oxygen diffusion layer, the gate insulating layer and the gate electrode layer can be formed over the upper surface and side surfaces of the hard mask.

The gate electrode does not necessarily contain the gate insulating layer and/or the gate electrode layer over the upper surface of the hard mask. Although now shown in FIG. 12, in one embodiment, the gate electrode does not contain the gate insulating layer over the upper surface of the hard mask. In another embodiment, the gate electrode does not contain the gate electrode layer over the upper surface of the hard mask. In yet another embodiment, the gate electrode does not contain the gate insulating layer and the gate electrode layer over the upper surface of the hard mask.

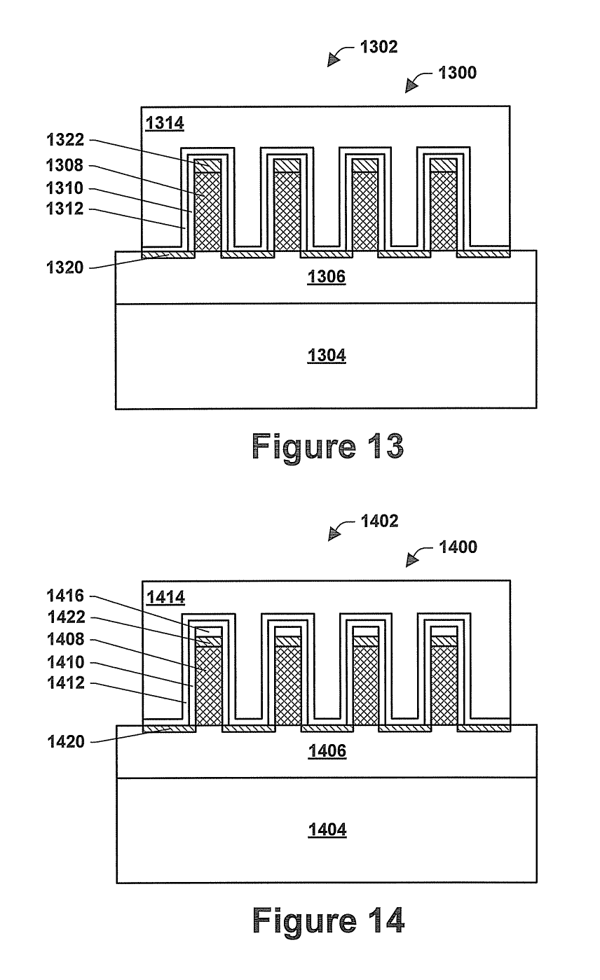

FIG. 13 illustrates a cross sectional view of another exemplary gate electrode 1300 of a multi-gate field effect transistor 1302. The gate electrode 1300 can contain a semiconductor substrate (e.g., silicon substrate) 1304; a dielectric layer (e.g., a buried silicon oxide layer or a BOX layer) 1306 over the semiconductor substrate; a fin 1308 over the dielectric layer; a first oxygen diffusion layer 1320 over the upper surface of the dielectric layer; a second oxygen diffusion layer 1322 over the upper surface of the fin; a gate insulating layer 1310 over the side surfaces of the fin, a gate electrode layer 1312 over the fin; and a polysilicon layer 1314 over the fin.

The gate electrode 1300 contains the semiconductor substrate 1304, the dielectric layer 1306, the fin 1308, the first oxygen diffusion layer 1320, the second oxygen diffusion layer 1322; the gate insulating layer 1310, the gate electrode layer 1312, and the polysilicon layer 1314 in the same manner as the gate electrode 1100 as described in connection with FIG. 11 except that the gate insulating layer is not formed over the upper surface of the dielectric layer (e.g., BOX layer) except portions of the upper surface of the dielectric layer that contact with the side surfaces of the gate insulating layer formed over the side surface of the fin in the same manner as the transistor 100 as described in connection with FIG. 1.

The gate electrode does not necessarily contain the gate insulating layer and/or the gate electrode layer over the upper surface of the second oxygen diffusion. Although now shown in FIG. 13, in one embodiment, the gate electrode does not contain the gate insulating layer over the upper surface of the second oxygen diffusion. In another embodiment, the gate electrode does not contain the gate electrode layer over the upper surface of the second oxygen diffusion. In yet another embodiment, the gate electrode does not contain the gate insulating layer and the gate electrode layer over the upper surface of the second oxygen diffusion.

FIG. 14 illustrates a cross sectional view of another exemplary gate electrode 1400 of a multi-gate field effect transistor 1402. The gate electrode 1400 can contain a semiconductor substrate (e.g., silicon substrate) 1404; a dielectric layer (e.g., a buried silicon oxide layer or a BOX layer) 1406 over the semiconductor substrate; a fin 1408 over the dielectric layer; a first oxygen diffusion layer 1420 over the upper surface of the dielectric layer; a second oxygen diffusion layer 1422 over the upper surface of the fin; a hard mask layer 1416 over the upper surface of the second oxygen diffusion layer; a gate insulating layer 1410 over the side surfaces of the fin, a gate electrode layer 1412 over the fin; and a polysilicon layer 1414 over the fin.

The gate electrode 1400 contains the semiconductor substrate 1404, the dielectric layer 1406, the fin 1408, the first oxygen diffusion layer 1420, the second oxygen diffusion layer 1422, the gate insulating layer 1410, the gate electrode layer 1412, and the polysilicon layer 1414 in the same manner as the gate electrode 1300 as described in connection with FIG. 13 except that the gate electrode further contains the hard mask layer 1416 over the over the upper surface of the second oxygen diffusion layer.

The gate electrode does not necessarily contain the gate insulating layer and/or the gate electrode layer over the upper surface of the hard mask. Although now shown in FIG. 14, in one embodiment, the gate electrode does not contain the gate insulating layer over the upper surface of the hard mask. In another embodiment, the gate electrode does not contain the gate electrode layer over the upper surface of the hard mask. In yet another embodiment, the gate electrode does not contain the gate insulating layer and the gate electrode layer over the upper surface of the hard mask.

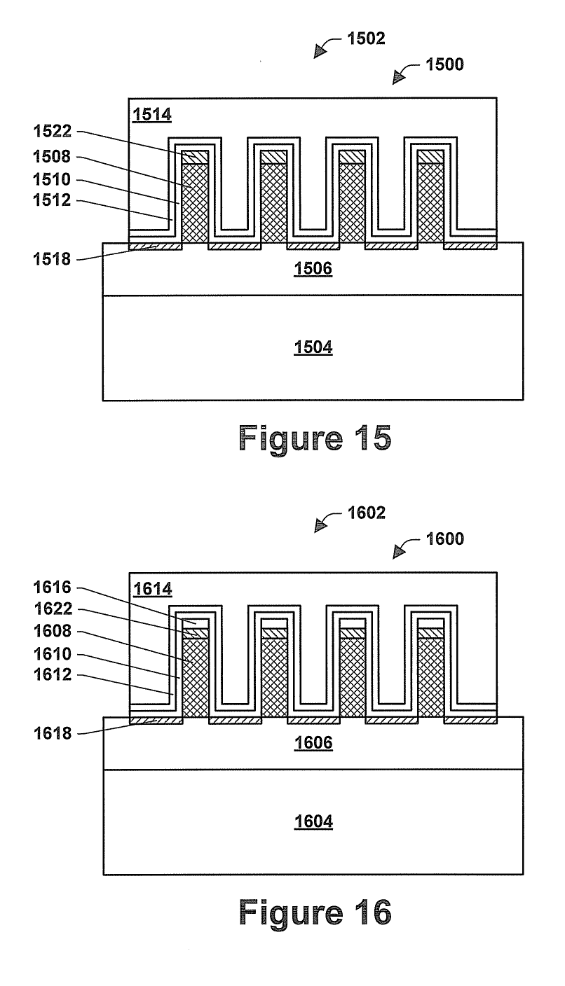

FIG. 15 illustrates a cross sectional view of another exemplary gate electrode 1500 of a multi-gate field effect transistor 1502. The gate electrode 1500 can contain a semiconductor substrate (e.g., silicon substrate) 1504; a dielectric layer (e.g., a buried silicon oxide layer or a BOX layer) 1506 over the semiconductor substrate; a fin 1508 over the dielectric layer; an oxygen diffusion barrier layer 1518 over the upper surface of the dielectric layer; a second oxygen diffusion layer 1522 over the upper surface of the fin; a gate insulating layer 1510 over the side surfaces of the fin, a gate electrode layer 1512 over the fin; and a polysilicon layer 1514 over the fin.

FIG. 16 illustrates a cross sectional view of another exemplary gate electrode 1600 of a multi-gate field effect transistor 1602. The gate electrode 1600 can contain a semiconductor substrate (e.g., silicon substrate) 1604; a dielectric layer (e.g., a buried silicon oxide layer or a BOX layer) 1606 over the semiconductor substrate; a fin 1608 over the dielectric layer; an oxygen diffusion barrier layer 1618 over the upper surface of the dielectric layer; a second oxygen diffusion layer 1622 over the upper surface of the fin; a hard mask 1616 over the second oxygen diffusion layer; a gate insulating layer 1610 over the side surfaces of the fin, a gate electrode layer 1612 over the fin; and a polysilicon layer 1614 over the fin.

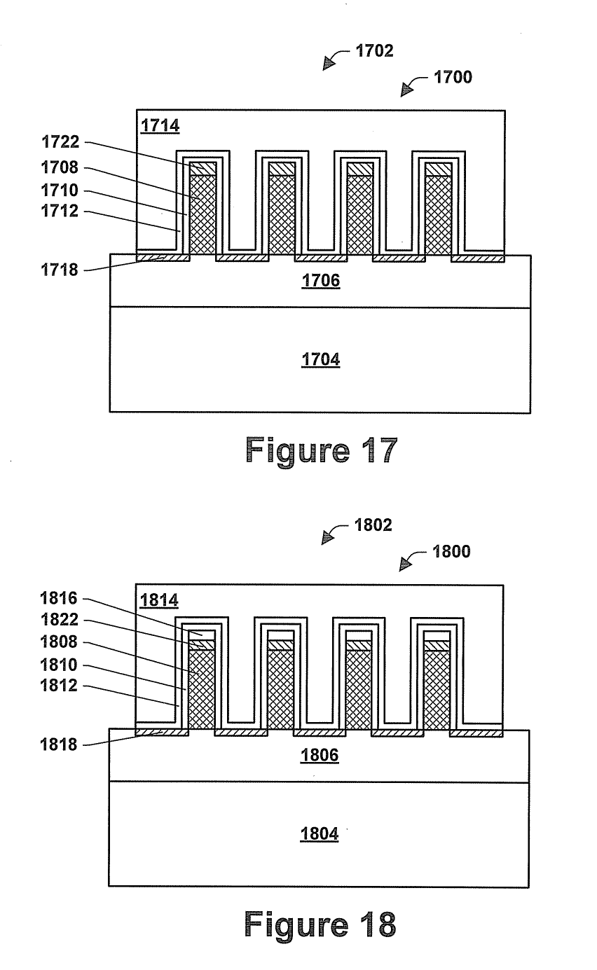

FIG. 17 illustrates a cross sectional view of another exemplary gate electrode 1700 of a multi-gate field effect transistor 1702. The gate electrode 1700 can contain a semiconductor substrate (e.g., silicon substrate) 1704; a dielectric layer (e.g., a buried silicon oxide layer or a BOX layer) 1706 over the semiconductor substrate; a fin 1708 over the dielectric layer; an oxygen diffusion barrier layer 1718 over the upper surface of the dielectric layer; a second oxygen diffusion layer 1722 over the upper surface of the fin; a gate insulating layer 1710 over the side surfaces of the fin, a gate electrode layer 1712 over the fin; and a polysilicon layer 1714 over the fin.

The gate electrode 1700 contains the semiconductor substrate 1704, the dielectric layer 1706, the fin 1708, the oxygen diffusion barrier layer 1718, the second oxygen diffusion layer 1722; the gate insulating layer 1710, the gate electrode layer 1712, and the polysilicon layer 1714 in the same manner as the gate electrode 1500 as described in connection with FIG. 15 except that the gate insulating layer is not formed over the upper surface of the dielectric layer (e.g., BOX layer) except portions of the upper surface of the dielectric layer that contact with the side surfaces of the gate insulating layer formed over the side surface of the fin in the same manner as the transistor 100 as described in connection with FIG. 1.

FIG. 18 illustrates a cross sectional view of another exemplary gate electrode 1800 of a multi-gate field effect transistor 1802. The gate electrode 1800 can contain a semiconductor substrate (e.g., silicon substrate) 1804; a dielectric layer (e.g., a buried silicon oxide layer or a BOX layer) 1806 over the semiconductor substrate; a fin 1808 over the dielectric layer; an oxygen diffusion barrier layer 1818 over the upper surface of the dielectric layer; a second oxygen diffusion layer 1822 over the upper surface of the fin; a hard mask 1816 over the second oxygen diffusion layer; a gate insulating layer 1810 over the side surfaces of the fin, a gate electrode layer 1812 over the fin; and a polysilicon layer 1814 over the fin.

The gate electrode 1800 contains the semiconductor substrate 1804, the dielectric layer 1806, the fin 1808, the first oxygen diffusion barrier layer 1818, the second oxygen diffusion layer 1822, the hard mask 1816, the gate insulating layer 1810, the gate electrode layer 1812, and the polysilicon layer 1814 in the same manner as the gate electrode 1700 as described in connection with FIG. 17 except that the gate electrode further contains the hard mask layer 1816 over the over the upper surface of the second oxygen diffusion layer.

In FIGS. 15-18, the gate insulating layer and/or the gate electrode layer are not necessarily formed over the upper surface of the second oxygen diffusion layer or the hard mask layer. Although now shown in FIG. 15-18, in one embodiment, the gate electrode does not contain the gate insulating layer over the upper surface of the second oxygen diffusion layer or the hard mask. In another embodiment, the gate electrode does not contain the gate electrode layer over the upper surface of the second oxygen diffusion layer or the hard mask. In yet another embodiment, the gate electrode does not contain the gate insulating layer and the gate electrode layer over the upper surface of the second oxygen diffusion layer or the hard mask.

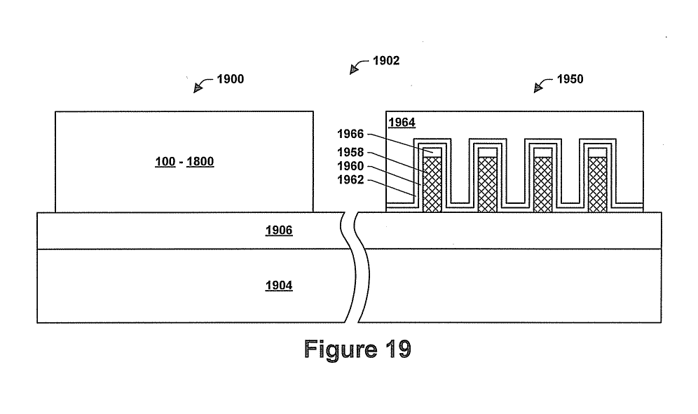

FIG. 19 illustrates a cross sectional view of exemplary gate electrodes of a multi-gate field effect transistor 1902. The transistor 1902 contains a first gate electrode 1900 and a second gate electrode 1950. The first gate electrode 1900 can be selected from the group consisting of gate electrodes 100, 200, 300, 400, 500, 600, 700, 800, 900, 1000, 1100, 1200, 1300, 1400, 1500, 1600, 1700, and 1800 as described in connection with FIGS. 1-18. The transistor contains the first gate electrode 1900 and the second gate electrode 1950 on one single semiconductor substrate (e.g., silicon substrate) 1904. The transistor can contain a dielectric layer (e.g., a buried silicon oxide layer or a BOX layer) 1906 over the semiconductor substrate and the transistor can contain the gate electrodes over the dielectric layer.

The gate electrode 1950 can contain a fin 1958 over the dielectric layer; a hard mask layer 1966 over the fin; a gate insulating layer 1960 over the side surfaces of the fin; a gate electrode layer 1962 over the fin; and a polysilicon layer 1964 over the fin. Although not shown in FIG. 19 for the purpose of brevity, in one embodiment, the gate electrode does not contain hard mask layer over the fin. The gage electrode contains the gate insulating layer over the upper surface of the dielectric layer.

The first gate electrode 1900 can have a smaller effective work function than the second gate electrode 1950. In one embodiment, the first gate electrode can have a smaller effective work function than the second gate electrode. The first gate electrode can have an effective work function smaller than about 4.6 eV and the second gate electrode can have an effective work function larger than about 4.6 eV. In another embodiment, the first gate electrode can have a smaller effective work function than the second gate electrode by about 0.2 eV or more and about 1.2 eV or less. In yet another embodiment, the first gate electrode can have a smaller effective work function than the second gate electrode by about 0.4 eV or more and about 1.0 eV or less.

In another embodiment, the first gate electrode 1900 can have a larger effective work function than the second gate electrode 1950. In one embodiment, the first gate electrode can have a larger effective work function than the second gate electrode. The first gate electrode can have an effective work function larger than about 4.6 eV and the second gate electrode can have an effective work function smaller than about 4.6 eV. In another embodiment, the first gate electrode can have a larger effective work function than the second gate electrode by about 0.2 eV or more and about 1.2 eV or less. In yet another embodiment, the first gate electrode can have a larger effective work function than the second gate electrode by about 0.4 eV or more and about 1.0 eV or less.

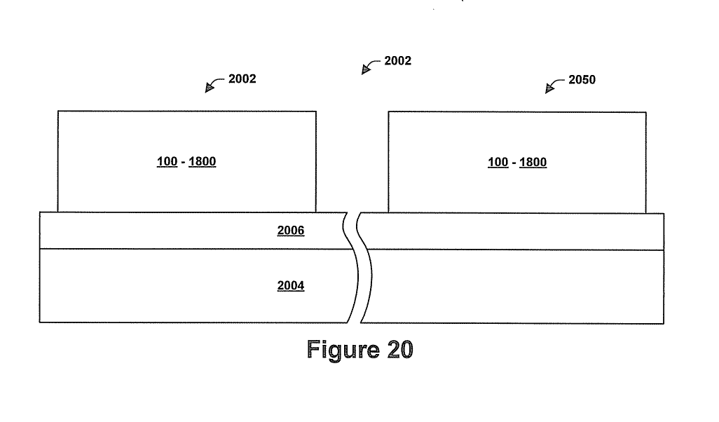

FIG. 20 illustrates a cross sectional view of gate electrodes of an exemplary multi-gate field effect transistor 2002. The transistor 2002 contains a first gate electrode 2000 and a second gate electrode 2050. The transistor contains the two gate electrodes on one single semiconductor substrate (e.g., silicon substrate) 2004. The transistor can contain a dielectric layer (e.g., a buried silicon oxide layer or a BOX layer) 2006 over the semiconductor substrate and the transistor can contain the two gate electrode over the dielectric layer.

The first gate electrode 2000 and the second gate electrode 2050 can be selected individually from the group consisting of gate electrodes 100, 200, 300, 400, 500, 600, 700, 800, 900, 1000, 1100, 1200, 1300, 1400, 1500, 1600, 1700, and 1800 as described in connection with FIGS. 1-18. In one embodiment, the first transistor 2102 can be selected from the group consisting of gate electrodes 300, 400, 500, 600, 1500, 1600, 1700, and 1800 as described in connection with FIGS. 3-6 and 15-18. The second transistor 2050 can be selected from the group consisting of gate electrodes 700, 800, 900, 1000, 1100, 1200, 1300, and 1400 as described in connection with FIGS. 7-14.

The two or more gate electrodes can have any suitable effective work function. The first gate electrode 2000 can have a smaller effective work function than the second gate electrode 2050. In one embodiment, the first gate electrode can have a smaller effective work function than the second gate electrode. The first gate electrode can have an effective work function smaller than about 4.6 eV and the second gate electrode can have an effective work function larger than about 4.6 eV. In another embodiment, the first gate electrode can have a smaller effective work function than the second gate electrode by about 0.2 eV or more and about 1.2 eV or less. In yet another embodiment, the first gate electrode can have a smaller effective work function than the second gate electrode by about 0.4 eV or more and about 1.0 eV or less.

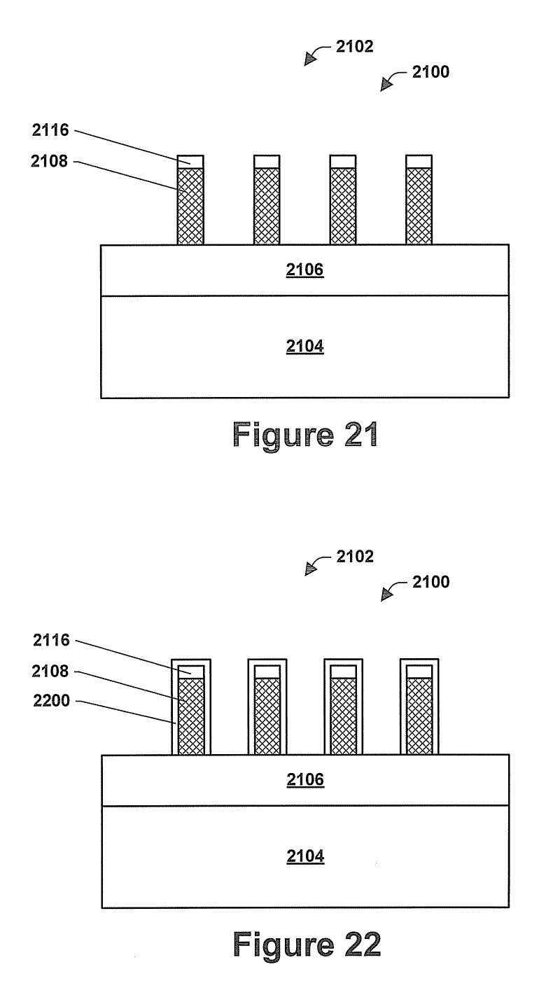

Referring to FIGS. 21 to 24 and FIGS. 25 to 28, two of many possible exemplary embodiments of forming a gate electrode of a multi-gate field effect transistor are specifically illustrated. FIG. 21 is a cross sectional view of an intemiediate state of an exemplary gate electrode 2100 of a multi-gate field effect transistor 2102. FIG. 21 illustrates forming a fin 2108 over a dielectric layer 2106 and a semiconductor substrate 2104. FIG. 21 further illustrates forming a hard mask layer 2116 over the upper surface of the fin. Although not shown for the purpose of brevity, in some embodiments, the method does not involve forming a hard mask layer over the fin.

The dielectric layer can be a buried silicon oxide layer or a BOX layer, and can be formed over the semiconductor substrate by any suitable deposition technique. Examples of deposition techniques include chemical vapor deposition (CVD) such as plasma enhanced chemical vapor deposition (PECVD), low-pressure chemical vapor deposition (LPCVD), high-pressure chemical vapor deposition (HPCVD), or the like. The fin and the hard mask can be formed by forming a layer containing a fin material over the dielectric layer and a layer containing a hard mask material over the fin material layer, and removing portions of the layers by using a suitable patterned resist layer. The patterned resist layer can be formed by optical lithography, sidewall image transfer technique, or the like.

The portions of the fin material layer and the hard mask material layer can be removed by contacting the layers with any suitable etchant that does not substantially damage and/or remove other components of the transistor. Choice of a suitable process and reagents of etching depends on, for example, the fin material, the hard mask material, the width and height of the fin, the desired implementations of the transistor being fabricated, or the like.

Wet etching and/or dry etching containing isotropic etching and/or anisotropic etching can be employed. Examples of wet etchants for the silicon layer include tetraalkylammonium hydroxides (e.g., tetramethylammonium hydroxide (TMAH)) and alkali metal hydroxides (e.g., a potassium hydroxide (KOH) and cerium hydroxide (CeOH)). Examples of dry etching include reactive ion etching (RIB) using, for example, a mixture gas containing HBr (e.g., HBr and O₂ mixture gas, HBr/NF₃/He and O₂ mixture gas, SF₆, HBr and O₂ mixture gas). The mixture may further include Cl₂.

FIG. 22 illustrates forming a gate insulating layer 2200 over the side surfaces of the fin 2108. A gate insulating layer is not formed over the upper surface of the dielectric layer except portions of the upper surface of the dielectric layer that contact with the side surfaces (e.g., edges) of the gate insulating layer formed over the side surface of the fin.

The gate insulating layer can be formed by forming a layer containing a gate insulating material and a protecting layer over the gate insulating material layer, removing portions of the gate insulating material layer and the protecting layer over the upper surface of the dielectric layer, and removing the remaining portions of the protecting layer. The portions of the gate insulating material layer and the protecting layer over the upper surface of the dielectric layer are removed so that the resultant gate insulating layer is not formed over the upper surface of the dielectric layer except portions of the upper surface of the dielectric layer that contact with the side surfaces (e.g., edges) of the gate insulating layer formed over the side surface of the fin. When removing portions of the gate insulating material layer and the protecting layer over the dielectric layer, portions of the gate insulating material layer and the protecting layer over the upper surface of the fin can be also removed.

The portions of the gate insulating material layer and the protecting layer can be removed by any suitable technique including anisotropic reactive ion etching (RIE). The remaining protecting layer can be removed by any suitable technique including wet etching. The protecting layer can contain any suitable material so that the protecting layer can protect the underlying gate insulating material layer from the removing process (e.g., RIB). For example, the protecting layer can contain the same material as the material of the gate metal layer 110 as described in connection with FIG. 1.

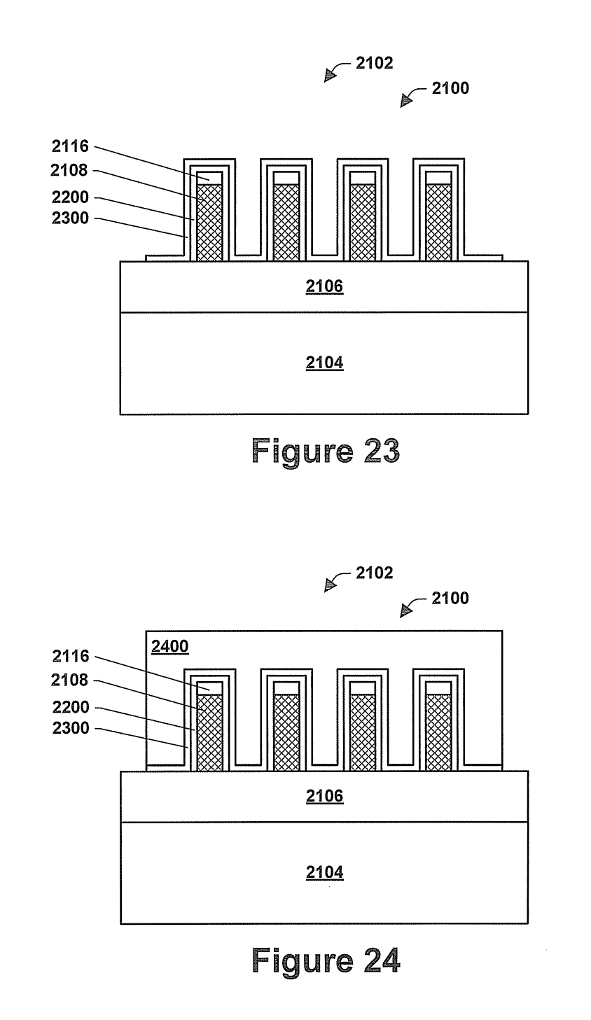

FIG. 23 illustrates forming a gate electrode layer 2300 over the fin. The gate electrode layer can be fonned by any suitable technique including CVD.

FIG. 24 illustrates forming a polysilicon layer 2400 over the fin. The polysilicon layer can be formed over the fin by any suitable technique including CVD.

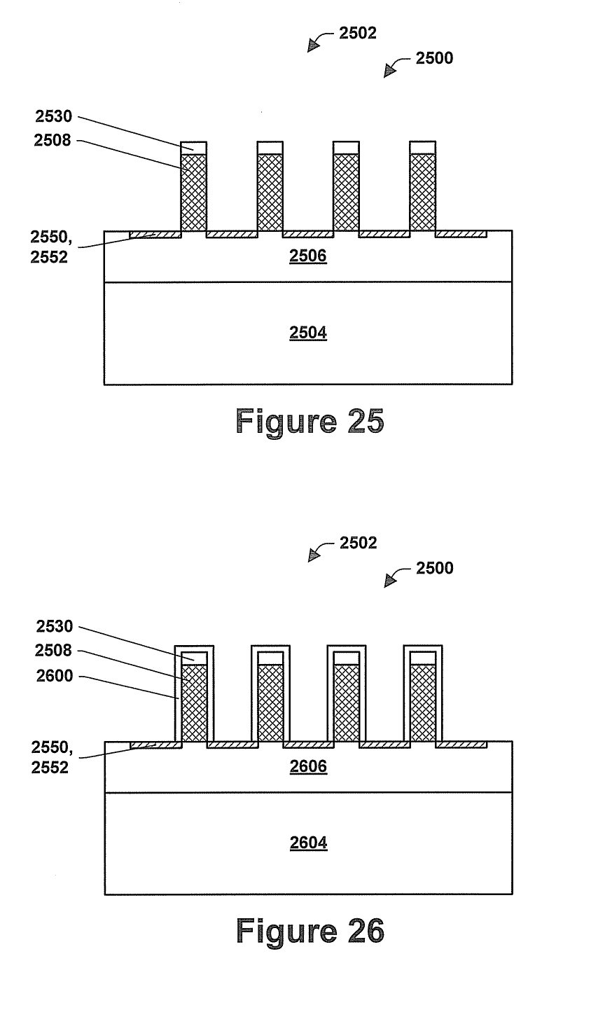

FIGS. 25-28 illustrate another exemplary embodiment of forming a gate electrode of a multi-gate field effect transistor. FIG. 25 is a cross sectional view of an intermediate state of an exemplary gate electrode 2500 of a multi-gate field effect transistor 2502. FIG. 25 illustrates forming a fin 2508 over a dielectric layer 2506 and a semiconductor substrate 2504.

FIG. 25 further illustrates forming a layer 2530 over the upper surface of the fin. The layer over the fin can contain one or more layers. In one embodiment, the layer over the fin contains a hard mask layer. In another embodiment, the layer over the fin contains a second oxygen diffusion layer. In another embodiment, the layer over the fin contains a second oxygen diffusion layer over the fin and a hard mask layer over the second oxygen diffusion layer. Although not shown for the purpose of brevity, in some embodiments, the method does not involve forming a layer over the fin.

FIG. 25 further illustrates forming an oxygen diffusion barrier layer 2550 or a first oxygen diffusion layer 2552 over the upper surface of the dielectric layer 2506. The oxygen diffusion barrier layer can be formed by any suitable technique. In one embodiment, the oxygen diffusion barrier layer is formed by introducing nitrogen into the upper surface of the dielectric layer. Nitrogen can be introduced by any suitable technique. Example of techniques for introducing nitrogen into the upper surface of the dielectric layer include thermal nitrization using ammonia gas (NH₃), plasma nitrization using N₂ plasma or NH₃ plasma, nitrogen ion implantation followed by annealing, or the like.

The first oxygen diffusion layer 2552 can be formed by any suitable technique. In one embodiment, the oxygen diffusion layer is formed by introducing oxygen into the upper surface of the dielectric layer. Oxygen can be introduced by any suitable technique. Examples of techniques for introducing oxygen into the upper surface of the dielectric layer include implantation of ions of rare gas (e.g., xenon (Xe) or krypton (Kr)) followed by thermal oxidation, oxygen ion implantation followed by annealing, or the like. In another embodiment, the oxygen diffusion layer is formed by depositing oxides (e.g., silicon oxides). For example, a silicon oxide is formed by CVD using TEOS and oxygen. The first oxygen diffusion layer can be formed in the same manner as the second diffusion layer. Although not shown in FIG. 25 for the purpose of brevity, in some embodiments, the method does not involve forming an oxygen diffusion barrier layer or a first oxygen diffusion layer over the upper surface of the dielectric layer.

FIG. 26 illustrates forming a gate insulating layer 2600 over the side surfaces of the fin. In one embodiment, a gate insulating layer is not formed over the upper surface of the dielectric layer except portions of the upper surface of the dielectric layer that contact with the side surfaces of the gate insulating layer formed over the side surface of the fin. In another embodiment, a gate insulating layer is formed over the upper surface of the dielectric layer. The gate insulating layer can be formed in a similar manner to that of the gate insulating layer 2200 as described in connection with FIG. 22.

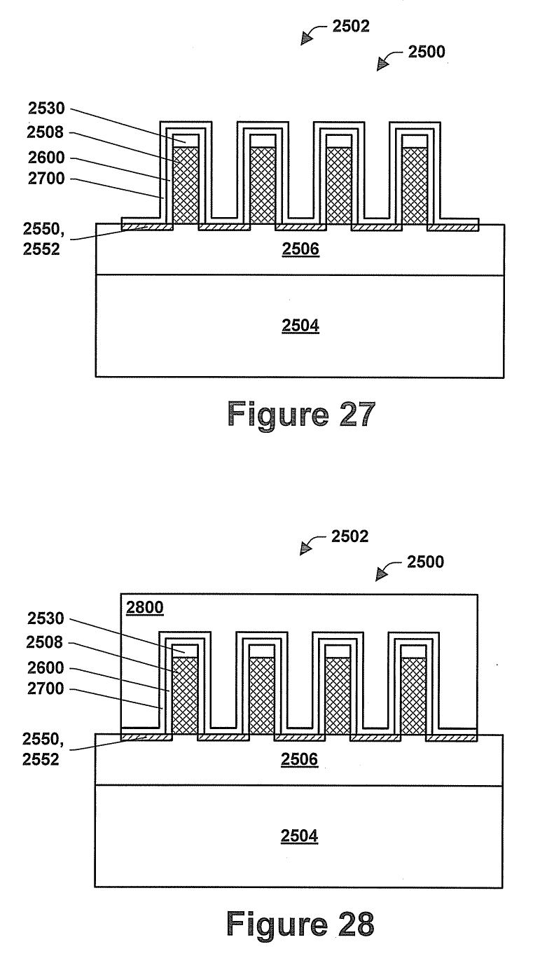

FIG. 27 illustrates forming a gate electrode layer 2700 over the fin. The gate electrode layer can be formed over the fin by any suitable technique including CVD.

FIG. 28 illustrates forming a polysilicon layer 2800 over the fin. The polysilicon layer can be formed over the fin by any suitable technique including CVD.

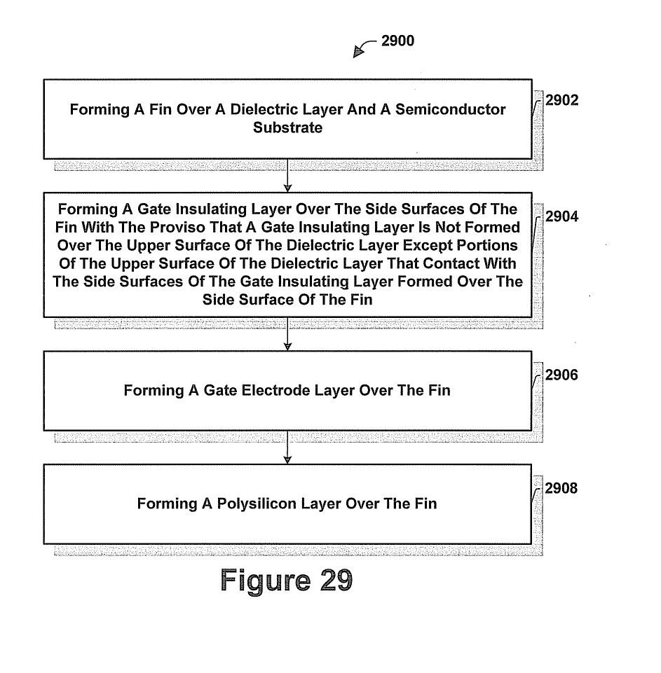

FIG. 29 illustrates an exemplary methodology 2900 of forming a gage electrode of a multi-gate metal field effect transistor. At 2902, a fin is formed over a dielectric layer and a semiconductor substrate. At 2904, a gate insulating layer is formed over the side surfaces of the fin. The method, however, does not involve forming a gate insulating layer over the upper surface of the dielectric layer except portions of the upper surface of the dielectric layer that contact with the side surfaces of the gate insulating layer formed over the side surface of the fin. At 2906, a gate electrode layer is formed over the fin. At 2908, a polysilicon layer is formed over the fin. In one embodiment, the method involves forming a hard mask over the upper surface of the fin.

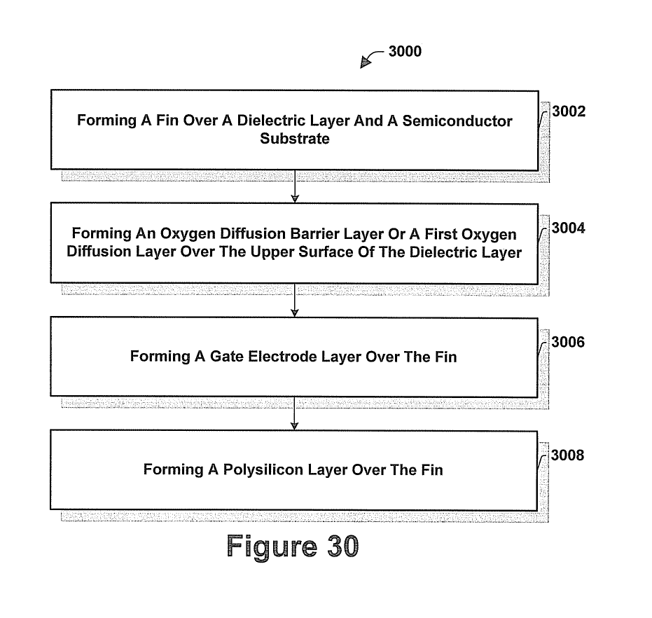

FIG. 30 illustrates another exemplary methodology 3000 of forming a gate electrode of a multi-gate field effect transistor. At 3002, a fin is foamed over a dielectric layer and a semiconductor substrate. At 3004, an oxygen diffusion barrier layer or a first oxygen diffusion layer is fatmed over the upper surface of the dielectric layer. At 3006, a gate insulating layer is foamed over the side surfaces of the fin. At 3008, a gate electrode layer is formed over the fin. At 3010, a polysilicon layer is formed over the fin. In one embodiment, the method involves forming a hard mask over the upper surface of the fin.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

What is claimed is:

1. A gate electrode of a multi-gate metal field effect transistor, comprising:
a semiconductor substrate;
a dielectric layer over the semiconductor substrate;
a fin over the dielectric layer;
a gate insulating layer over the side surfaces of the fin, the gate electrode not comprising a gate insulating layer over the upper surface of the dielectric layer except portions of the upper surface of the dielectric layer that contact with the side surfaces of the gate insulating layer formed over the side surface of the fin;
a gate electrode layer over the fin; and
a polysilicon layer over the fin.

2. The gate electrode of claim 1 further comprising a hard mask over the upper surface of the fin.

3. The gate electrode of claim 1 having an effective work function smaller than about 4.6 eV.

4. The gate electrode of claim 1, wherein a portion of gate electrode is directly in contact with the upper surface of the dielectric layer.

5. A gate electrode of a multi-gate metal field effect transistor, comprising:
a semiconductor substrate;
a dielectric layer over the semiconductor substrate;
a fin over the dielectric layer;
an oxygen diffusion barrier layer or a first oxygen diffusion layer over the upper surface of the dielectric layer;
a gate insulating layer over the side surfaces of the fin;
a gate electrode layer over the fin; and
a polysilicon layer over the fin.

6. The gate electrode of claim 5 further comprising a hard mask over the upper surface of the fin.

7. The gate electrode of claim 5 with the proviso that the gate electrode does not comprise a gate insulating layer over the upper surface of the dielectric layer except portions of the upper surface of the dielectric layer that contact with the side surfaces of the gate insulating layer formed over the side surface of the fin.

8. The gate electrode of claim 5 further comprising a second oxygen diffusion layer over the upper surface of the fin.

9. The gate electrode of claim 5 further comprising a second oxygen diffusion layer over the upper surface of the fin and a hard mask over the upper surface of the second oxygen diffusion layer.

10. The gate electrode of claim 5 comprising the oxygen diffusion barrier layer over the upper surface of the dielectric layer and having an effective work function smaller than about 4.6 eV.

11. The gate electrode of claim 5 comprising the first oxygen diffusion layer over the upper surface of the dielectric layer and having an effective work function larger than about 4.6 eV.

12. A multi-gate metal field effect transistor comprising a first gate electrode and a second gate electrode,
the first gate electrode comprising:
a semiconductor substrate;
a dielectric layer over the semiconductor substrate;
a fin over the dielectric layer;
a gate insulating layer over the side surfaces of the fin and the upper surface of the dielectric layer;
a gate electrode layer over the fin; and
a polysilicon layer over the fin;
the second gate electrode is selected from the group consisting of the gate electrode of claim 1 and the gate electrode of claim 5; and
the first gate electrode having an effective work function that is smaller than an effective work function of the second gate electrode.

13. The gate electrode of claim 12, wherein the first gate electrode can have a smaller effective work function than the second gate electrode by about 0.2 eV or more and about 1.2 eV or less.

14. A multi-gate metal field effect transistor comprising a first gate electrode and a second gate electrode,
the first gate electrode is selected from the group consisting of the gate electrode of claim 1 and the gate electrode of claim 5;
the second gate electrode is selected from the group consisting of the gate electrode of claim 1 and the gate electrode of claim 5; and
the first gate electrode having an effective work function smaller than about 4.6 eV and the second gate electrode having an effective work function larger than about 4.6 eV.

15. The gate electrode of claim 14, wherein the first gate electrode can have a smaller effective work function than the second gate electrode by about 0.2 eV or more and about 1.2 eV or less.

16. A method of making a gate electrode of a multi-gate metal field effect transistor, comprising:
forming a fin over a dielectric layer and a semiconductor substrate;
forming a gate insulating layer over the side surfaces of the fin with the proviso that a gate insulating layer is not formed over the upper surface of the dielectric layer except portions of the upper surface of the dielectric layer that contact with the side surfaces of the gate insulating layer formed over the side surface of the fin;
forming a gate electrode layer over the fin; and
forming a polysilicon layer over the fin.

17. The method of claim 16 further comprising forming a hard mask over the upper surface of the fin.

18. A method of making a gate electrode of a multi-gate metal field effect transistor, comprising:
forming a fin over a dielectric layer and a semiconductor substrate;
forming an oxygen diffusion barrier layer or a first oxygen diffusion layer over the upper surface of the dielectric layer;
forming a gate insulating layer over the side surfaces of the fin;
forming a gate electrode layer over the fin; and
forming a polysilicon layer over the fin.

19. The method of claim 18 further comprising forming a hard mask over the upper surface of the fin.

20. The method of claim 18 further comprising forming a second oxygen diffusion layer over the upper surface of the fin and forming a hard mask layer over the second oxygen diffusion layer.
